(19) United States
(12) Patent Application Publication
(10) Pub. No.: US 2022/0185032 A1
(43) Pub. Date: Jun. 16, 2022

(54) METHOD AND APPARATUS FOR PREDICTING TIRE WEAR USING MACHINE LEARNING

(71) Applicants: Hyundai Motor Company, Seoul (KR); Kia Corporation, Seoul (KR)

(72) Inventors: Jae Han CHOI, Whasung-Si (KR); Jae Wan KWON, Whasung-Si (KR)

(73) Assignees: Hyundai Motor Company, Seoul (KR); Kia Corporation, Seoul (KR)

(21) Appl. No.: 17/470,806

(22) Filed: Sep. 9, 2021

(30) Foreign Application Priority Data
Dec. 16, 2020 (KR) 10-2020-0176787

(51) Int. Cl. B60C 11/24; G06N 20/20; G06F 17/18; G01M 17/02

(52) U.S. Cl. CPC B60C 11/246; G01M 17/02; G06F 17/18; G06N 20/20

(57) ABSTRACT

A method for predicting tire wear in an apparatus mounted in a vehicle may include importing a tire wear database generated based on basic data, generating a dataset by preprocessing the basic data, classifying the dataset for each vehicle driving method, optimizing a hyper parameter for machine learning based on the classified dataset, and predicting a tire wear lifespan of the vehicle by performing machine learning on the optimized hyper parameter.

### CROSS-REFERENCE TO RELATED APPLICATION

The present application claims priority to Korean Patent Application No. 10-2020-0176787, filed on Dec. 16, 2020, the entire contents of which is incorporated herein for all purposes by this reference.

### BACKGROUND OF THE INVENTION

### Field of the Invention

The present invention relates to a tire wear prediction technology, and more particularly, to a tire wear prediction technology using artificial intelligence machine learning

### Description of Related Art

Tire wear lifespan is difficult to predict the amount of tire wear and wear patterns before performing practical tests/evaluations.

Currently, tire wear performance is being figured out through actual road driving (or actual road simulation indoor drum rotation test) after production of tire samples

Tire finite element method (FEM) analysis predicts wear according to tire pattern, internal structure, and tread compound, but is insufficient to development and utilization of tires due to low correlation with actual driving.

Accordingly, there is a demand for a method in which a tire developer can quantitatively analyze tire wear and predict a wear lifespan of tires in advance, preemptively taking action for problems which may occur in the future.

The information disclosed in this Background of the Invention section is only for enhancement of understanding of the general background of the invention and may not be taken as an acknowledgement or any form of suggestion that this information forms the prior art already known to a person skilled in the art.

### BRIEF SUMMARY

Various aspects of the present invention are directed to providing a tire wear prediction method using artificial intelligence machine learning and an apparatus therefor.

Various aspects of the present invention provide a tire wear prediction method using AI machine learning configured for preemptively taking action for future problems by facilitating the development of a virtual vehicle through early prediction and analysis of tire wear performance when evaluating tire wear before practical driving, and an apparatus therefor.

Various aspects of the present invention provide a multi output regression prediction model using a machine learning technique, configured for quantitatively performing data-based tire wear prediction based on a learning/prediction database frame built for development of a machine learning algorithm.

Various aspects of the present invention provide a tire wear prediction method using AI machine learning configured for facilitating real-time active control and operation management of autonomous vehicles/mobility vehicles by linking multi output regression prediction models using artificial intelligence machine learning techniques to vehicle controllers, infotainment systems, and mobility operators, and an apparatus therefor.

Various aspects of the present invention provide a tire wear prediction method using AI machine learning configured for performing relative comparison and contribution analysis of wear features for each tire wear influence factor, and an apparatus therefor.

The technical problems to be solved by the present inventive concept are not limited to the aforementioned problems, and any other technical problems not mentioned herein will be clearly understood from the following description by those skilled in the art to which various exemplary embodiments of the present invention pertains.

According to various aspects of the present invention, a method for predicting tire wear in an apparatus mounted in a vehicle may include importing a tire wear database generated based on basic data, generating a dataset by preprocessing the basic data, classifying the dataset for each vehicle driving method, optimizing a hyper parameter for machine learning based on the classified dataset, and predicting a tire wear lifespan of the vehicle by performing the machine learning on the optimized hyper parameter.

According to various exemplary embodiments of the present invention, the basic data may include explanatory variables and predictive variables obtained through a tire wear test of an actual vehicle, wherein the explanatory variables include at least one of vehicle information, vehicle driving information, tire information, and wheel alignment information, and the predictive variables include a wear lifespan of each tire groove.

According to various exemplary embodiments of the present invention, the preprocessing may include at least one of converting discrete variables and qualitative variables into quantitative variables, normalizing the quantitative variable, eliminating extreme values from among the predictive variables, and compensating for missing values of the explanatory variable.

According to various exemplary embodiments of the present invention, the hyper parameter may be optimized by eliminating a factor with importance lower than a predetermined value from the classified dataset through importance analysis for each tire wear factor based on the Least Absolute Shrinkage and Selection Operator (LASSO) model.

According to various exemplary embodiments of the present invention, the tire wear lifespan may be predicted based on a multi output regression analysis technique, and is predicted through the multi output regression analysis technique.

According to various exemplary embodiments of the present invention, the multi output regression analysis technique may include a random forest technique and a stochastic gradient boosting technique, and one of the random forest technique and the stochastic gradient boosting technique may be selectively used based on a number of the classified datasets.

According to various exemplary embodiments of the present invention, the method may further include outputting predicted tire lifespan information through an output device provided in the vehicle, and transmitting the predicted tire lifespan information to the other device.

According to various exemplary embodiments of the present invention, the other device may include at least one of a vehicle controller, a vehicle developer server, a driver terminal, and a mobility operator server.

According to various exemplary embodiments of the present invention, the method may further include optimizing a vehicle driving-related parameter by performing vehicle active control based on the predicted tire lifespan information, and the vehicle active control may include at least one of braking control, suspension control, steering wheel control, and turning control.

According to various exemplary embodiments of the present invention, the basic data may be collected from a sensor provided in the vehicle, and the basic data may include at least one of driving mode analysis information detected by an acceleration sensor built in an airbag control unit, wheel alignment change information detected by an electronic suspension device, vehicle weight change information detected by an auto-leveling device, tire pressure change information detected by a tire pressure monitoring system (TPMS), and driving climate environment information detected by an outdoor air temperature sensor in an air conditioner

According to various aspects of the present invention, a tire wear prediction apparatus may include a memory and a processor electrically connected to the memory, and the processor may import a tire wear database generated based on basic data from the memory or an external device, generate a dataset by preprocessing the basic data, classify the dataset for each vehicle driving method, optimize a hyper parameter for machine learning based on the classified dataset, and predict a tire wear lifespan of the vehicle by performing machine learning on the optimized hyper parameter.

According to various exemplary embodiments of the present invention, the basic data may include explanatory variables and predictive variables obtained through a tire wear test of an actual vehicle, and the explanatory variables may include at least one of vehicle information, vehicle driving information, tire information, and wheel alignment information, and the predictive variables may include a wear lifespan of each tire groove.

According to various exemplary embodiments of the present invention, the processor may include at least one of means for converting discrete variables and qualitative variables into quantitative variables, means for normalizing the quantitative variables, means for eliminating extreme values from among predictive variables, and means for compensating for missing values of the explanatory variables.

According to various exemplary embodiments of the present invention, the hyper parameter may be optimized by eliminating a factor with importance lower than a predetermined value from the classified dataset through importance analysis for each tire wear factor based on the Least Absolute Shrinkage and Selection Operator (LASSO) model.

According to various exemplary embodiments of the present invention, the tire wear lifespan may be predicted based on a multi output regression analysis technique, and is predicted through the multi output regression analysis technique.

According to various exemplary embodiments of the present invention, the multi output regression analysis technique may include a random forest technique and a stochastic gradient boosting technique, and the processor may selectively select any one of the random forest technique and the stochastic gradient boosting technique based on a number of the classified datasets.

According to various exemplary embodiments of the present invention, the processor may include at least one of means for controlling output of the predicted tire lifespan information or information processed based on the predicted tire lifespan information through an output device provided in the vehicle, and means for controlling transmission of the predicted tire lifespan information to the other device.

According to various exemplary embodiments of the present invention, the other device may include at least one of a vehicle controller, a vehicle developer server, a driver terminal, and a mobility operator server.

According to various exemplary embodiments of the present invention, the processor may optimize a vehicle driving-related parameter by performing vehicle active control based on the predicted tire lifespan information, and the vehicle active control may include at least one of braking control, suspension control, steering wheel control, and turning control.

According to various exemplary embodiments of the present invention, the basic data may be collected from a sensor provided in the vehicle, and the basic data may include at least one of driving mode analysis information detected by an acceleration sensor built in an airbag control unit, wheel alignment change information detected by an electronic suspension device, vehicle weight change information detected by an auto-leveling device, tire pressure change information detected by a tire pressure monitoring system (TPMS), and driving climate environment information detected by an outdoor air temperature sensor in an air conditioner

The technical problems to be solved as various exemplary embodiments of the present invention are not limited to the aforementioned problems, and any other technical problems not mentioned herein will be clearly understood from the following description by those skilled in the art to which various exemplary embodiments of the present invention pertains.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a flowchart for describing a method for predicting tire wear using machine learning according to various exemplary embodiments of the present invention;

FIG. 2 is a diagram for describing a basic data processing procedure for constructing a training dataset according to various exemplary embodiments of the present invention;

FIG. 3 is a diagram for describing a learning modeling process according to various exemplary embodiments of the present invention;

FIG. 4 is a diagram for describing a learning algorithm according to various exemplary embodiments of the present invention;

FIG. 5 is a diagram for describing a data purification process for AI learning/prediction according to various exemplary embodiments of the present invention.

FIG. 6 shows a specific example of a data purification process for AI learning/prediction according to FIG. 5;

FIG. 7 is a flowchart for describing an operation mechanism of a tire wear prediction apparatus according to various exemplary embodiments of the present invention;

FIG. 8 is a graph showing tire wear lifespans according to practical vehicle driving evaluation and prediction results of tire wear lifespan using a tire wear learning algorithm according to various exemplary embodiments of the present invention; and

FIG. 9 shows the AI learning prediction result for the rear wheel wear lifespan ratio according to a change in rear wheel camber.

It may be understood that the appended drawings are not necessarily to scale, presenting a somewhat simplified representation of various features illustrative of the basic principles of the present invention. The specific design features of the present invention as disclosed herein, including, for example, specific dimensions, orientations, locations, and shapes will be determined in part by the particularly intended application and use environment.

In the figures, reference numbers refer to the same or equivalent portions of the present invention throughout the several figures of the drawing.

### DETAILED DESCRIPTION

Reference will now be made in detail to various embodiments of the present invention(s), examples of which are illustrated in the accompanying drawings and described below. While the present invention(s) will be described in conjunction with exemplary embodiments of the present invention, it will be understood that the present description is not intended to limit the present invention(s) to those exemplary embodiments. On the other hand, the present invention(s) is/are intended to cover not only the exemplary embodiments of the present invention, but also various alternatives, modifications, equivalents and other embodiments, which may be included within the spirit and scope of the present invention as defined by the appended claims.

Hereinafter, various exemplary embodiments of the present invention will be described in detail with reference to the exemplary drawings. In adding the reference numerals to the components of each drawing, it may be noted that the identical or equivalent component is designated by the identical numeral even when they are displayed on other drawings. Furthermore, in describing the exemplary embodiment of the present invention, a detailed description of well-known features or functions will be ruled out in order not to unnecessarily obscure the gist of the present invention.

In describing the components of the exemplary embodiment according to various exemplary embodiments of the present invention, terms such as first, second, “A”, “B”, (a), (b), and the like may be used. These terms are merely intended to distinguish one component from another component, and the terms do not limit the nature, sequence or order of the constituent components. Unless otherwise defined, all terms used herein, including technical or scientific terms, have the same meanings as those generally understood by those skilled in the art to which various exemplary embodiments of the present invention pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

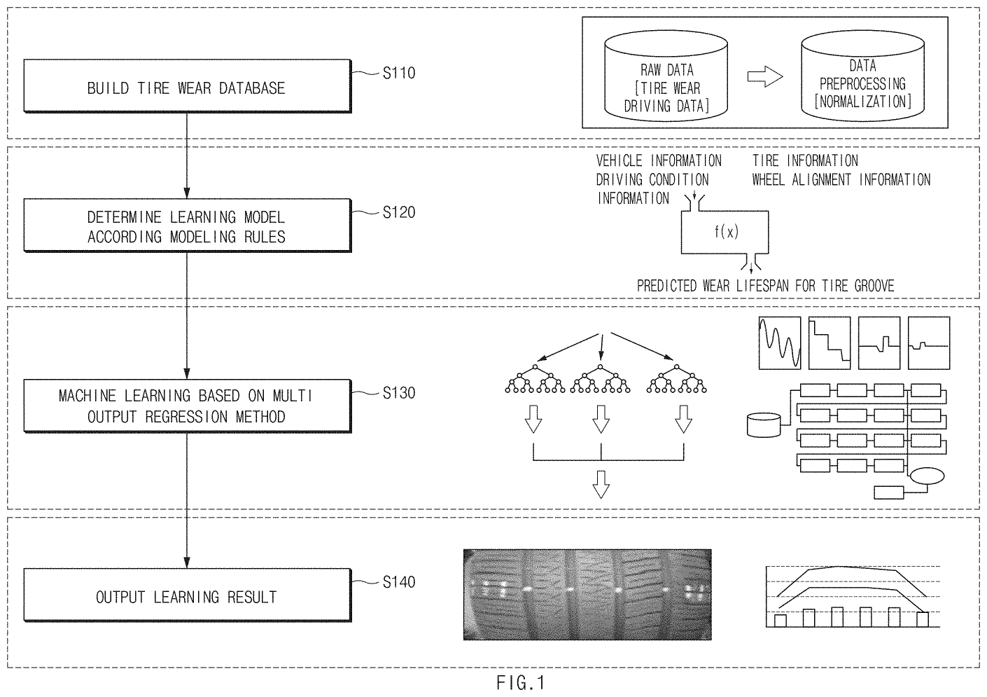

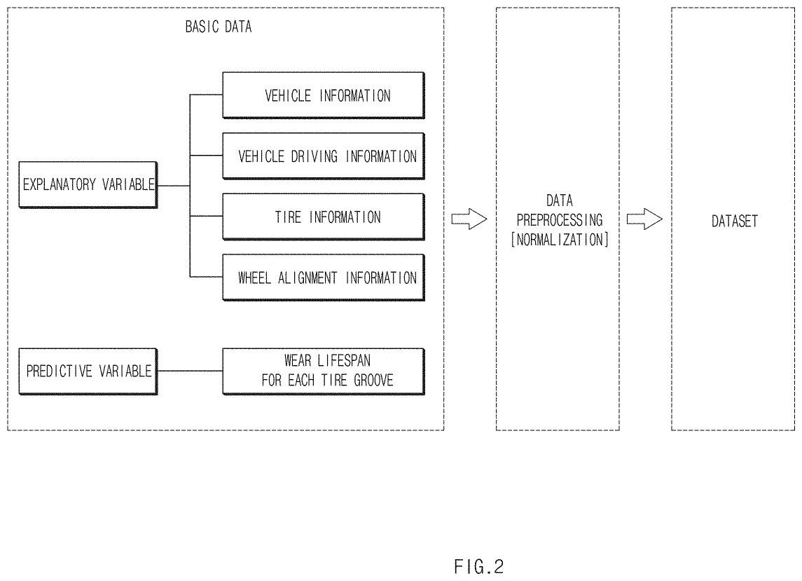

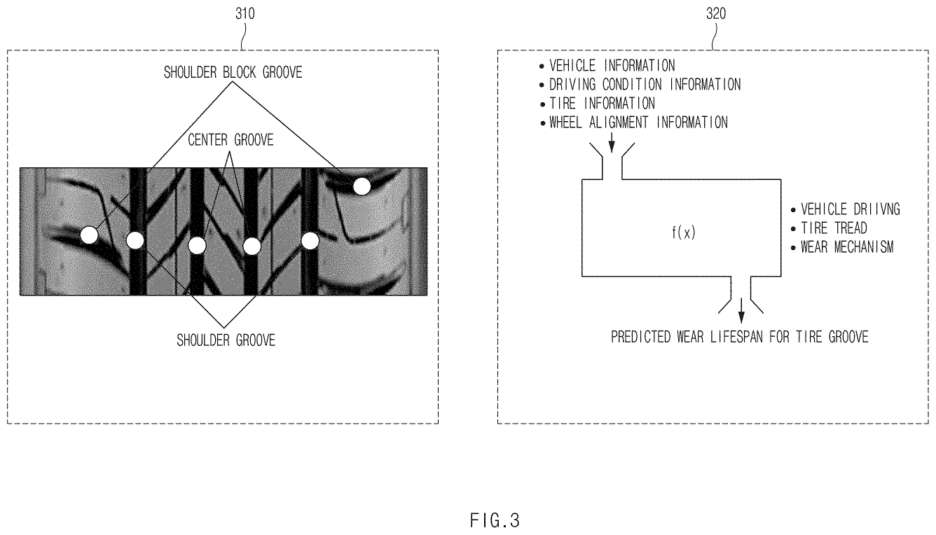

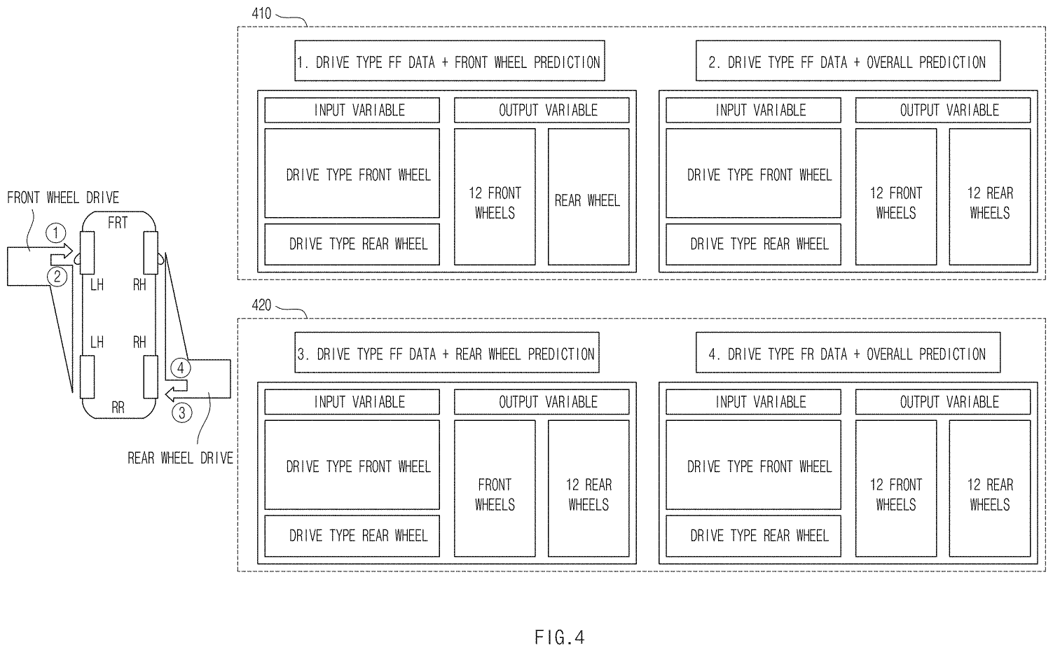

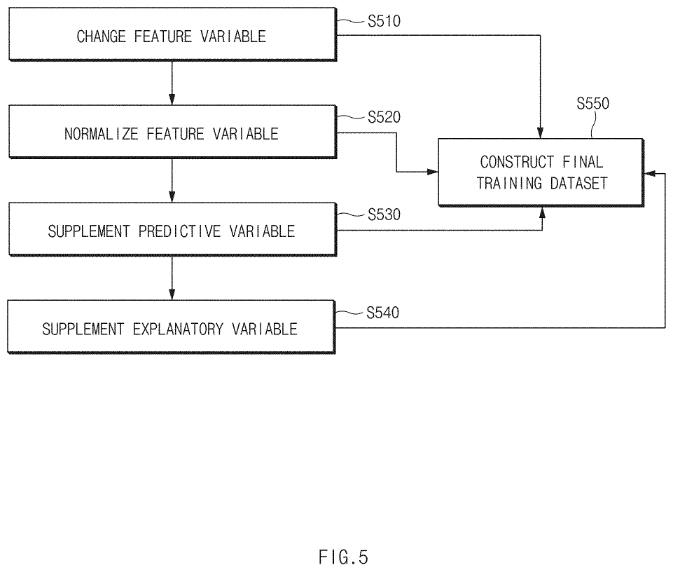

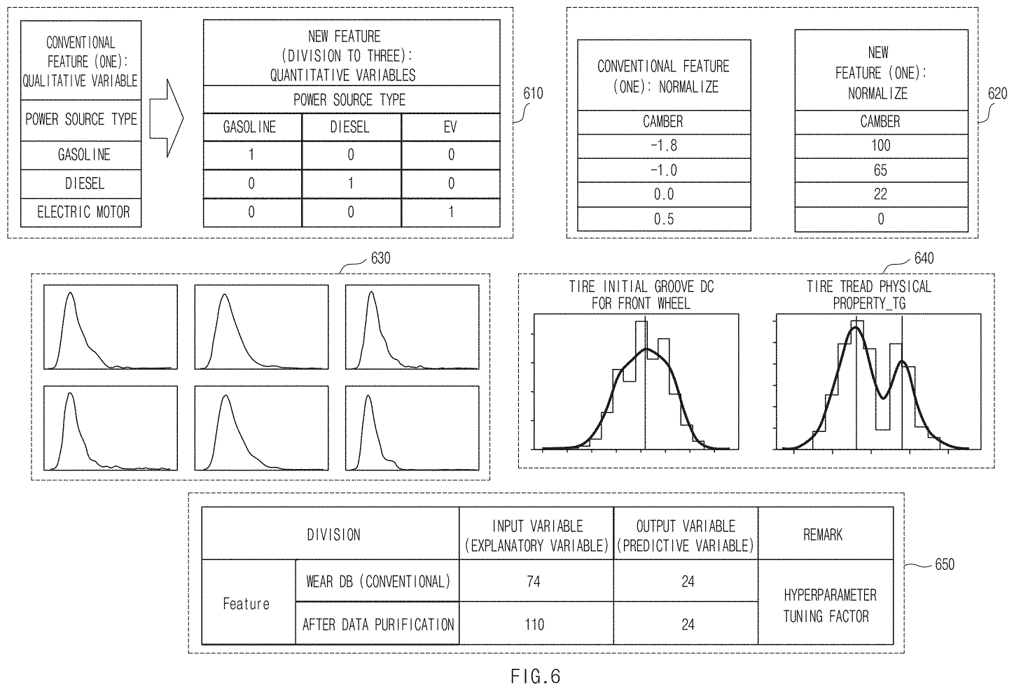

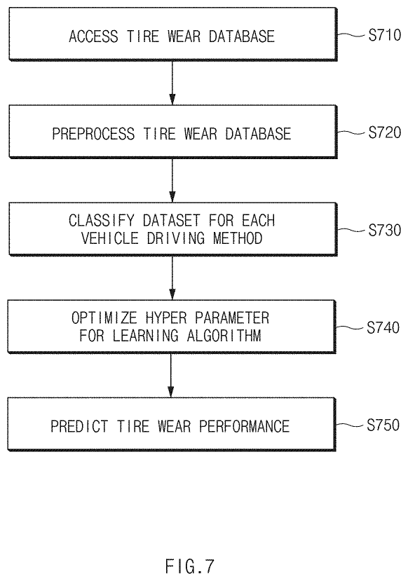

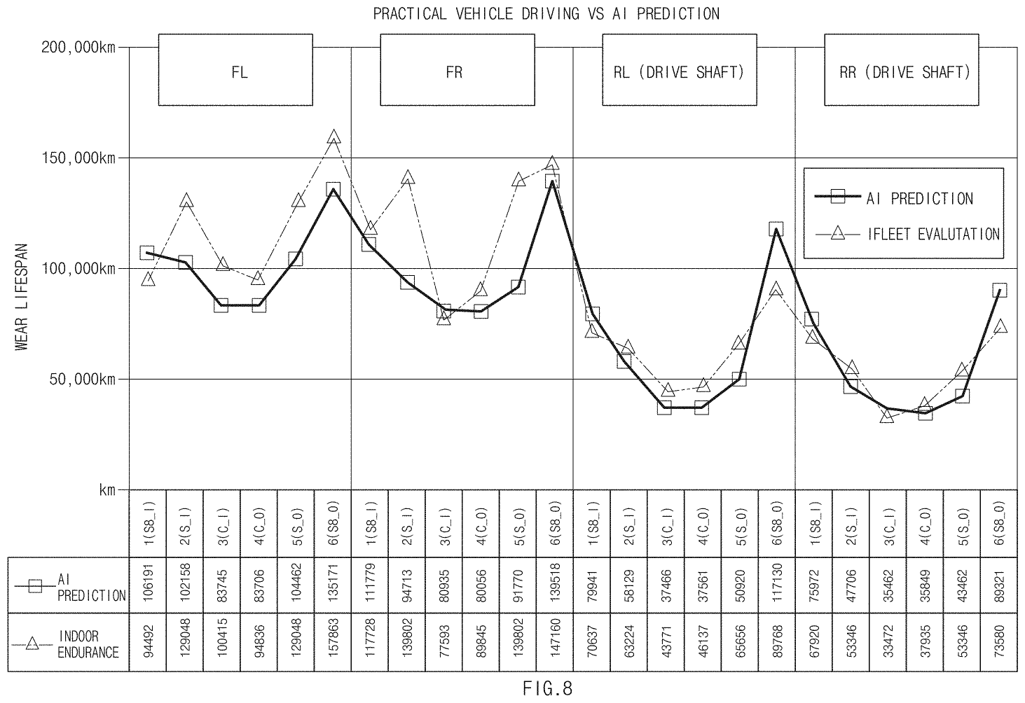

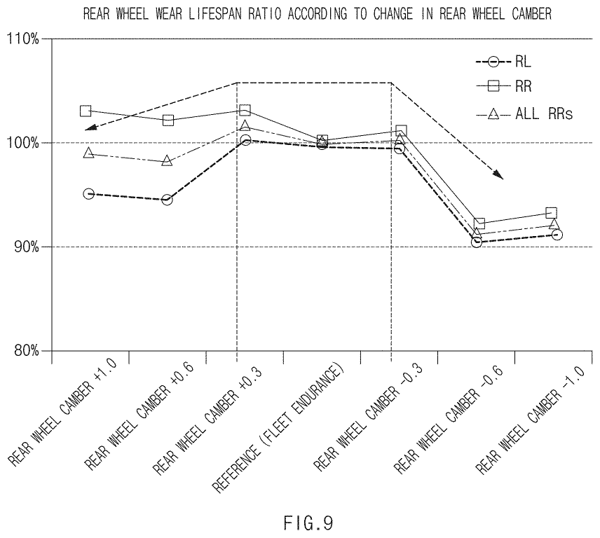

Hereinafter, embodiments of the present invention will be described in detail with reference to FIG. 1, FIG. 2, FIG. 3, FIG. 4, FIG. 5, FIG. 6, FIG. 7, FIG. 8 and FIG. 9.

FIG. 1 is a flowchart for describing a method for predicting tire wear using machine learning according to various exemplary embodiments of the present invention.

The method for predicting tire wear lifespan through basic data and AI modeling according to FIG. 1 may be implemented on a computer system in connection with a vehicle electronic control system, a vehicle sensor system, an infotainment system, a mobility operator server, a user terminal, and the like. Hereinafter, an apparatus of performing the method of predicting tire wear using machine learning will be simply referred to as a tire wear prediction apparatus.

Referring to FIG. 1, a tire wear database may be built in the tire wear prediction apparatus based on basic data (S110). As various exemplary embodiments of the present invention, the tire wear database may be built on a separate server which is linked to the tire wear prediction apparatus. Here, the basic data may be actual tire wear test data, and may include vehicle information, vehicle driving characteristic information, tire specification information, vehicle condition information, and/or the like. The basic data may be normalized and supplemented through data preprocessing.

The tire wear prediction apparatus may determine a learning model according to a predefined modeling rule (S120). The modeling rule may be configured to determine an expected wear lifespan for each tire groove based on vehicle information, information on vehicle driving conditions, tire specification information, wheel alignment information, and/or the like.

The tire wear prediction apparatus may perform machine learning based on a multi output regression method (S130). As an example, the multi output regression method may utilize the random forest technique configured for performing regression analysis or classification analysis, the stochastic gradient boosting technique, or the like, but is not limited thereto. The Least Absolute Shrinkage and Selection Operator (LASSO) technique that eliminates coefficients of unimportant variables and determines the importance of variables by penalizing regression may be utilized.

The random forest technique is a kind of ensemble learning method used for classification and regression analysis, for example, and may operate to output classification or average predicted values from a plurality of decision trees constructed in a training process.

The stochastic gradient boosting technique is a regression analysis learning technique that produces a predictive model in a form of an ensemble of decision trees, builds the model in a stage-wise fashion, and generalizes the model by allowing optimization of an arbitrary differentiable loss function.

Depending on the size of the dataset, either the random forest technique or the stochastic gradient boosting technique may be used.

When the number of training datasets is small—for example, about 1,000—Random Forest models may be utilized preferentially, and when datasets increases, Random Forest and stochastic gradient boosting may be utilized simultaneously and then selectively utilized according to performance. LASSO may be utilized to analyze the contribution of feature factors to tire wear performance.

After performing wear lifespan training and testing for each tire groove and performing 5-fold cross-validation, the performance is verified through the average value of five performances, and then the optimal machine learning model may be utilized according to the size and characteristics of the dataset.

Through the LASSO model, it is possible to determine the degree (coefficient) of influence of variables by analyzing the importance of each wear factor. As an example, a variable having a non-zero influence determined through the LASSO model may be classified as an important variable, and a variable having an influence of 0 may be classified as an unimportant variable.

The tire wear prediction apparatus may output a result of learning through a display provided (S140).

FIG. 2 is a view for describing a basic data processing procedure for constructing a training dataset according to various exemplary embodiments of the present invention.

Referring to FIG. 2, basic data may largely include explanatory variables and predictive variables.

The explanatory variables may include vehicle information, vehicle driving information, tire information, wheel alignment information, and/or the like.

The vehicle information may include at least one of vehicle class information, vehicle model information, power source information, power source name information, displacement information, electric vehicle battery capacity information, transmission type information, output (PS) information, torque (Kgf·m) information, driving method (front/rear wheel drive) information, 2WD/4WD information, suspension type (multi-link/CTBA) information, FR side weight (Kg) information, RR side weight (Kg) information, and front/rear wheel tire pressure (psi) information.

Driving mode information may include at least one of driving mode type (complex/high speed or the like) information, wear amount measurement timing (initial/middle/end or the like) information, and driving end date (date/season or the like) information.

The tire information may include at least one of manufacturer information, tire internal diameter (inch) information, tire pattern information, and tread physical property (Tg(° C.)) information, front wheel tire information, and rear wheel tire information.

Here, each of the front wheel tire information and the rear wheel tire information may include at least one of tread width (mm) information, aspect ratio (%) information, tread width/aspect ratio information, S.W height, and initial groove depth (Center/Out/Shoulder) (mm) information.

The wheel alignment information may largely include wheel alignment specification information and wheel alignment measurement load weight information.

The wear lifespan information for each tire groove may include wear lifespan information for the front/rear left and right tires.

The tire wear prediction apparatus may produce a dataset by normalizing data through preprocessing of the basic data. The tire wear database may include basic data and a dataset produced based on the basic data.

FIG. 3 is a diagram for describing a learning modeling process according to various exemplary embodiments of the present invention.

As shown in reference numeral 310 of FIG. 3, a minimum value among the wear lifespans of 24 grooves formed in four tires of front/rear and left/right wheels of a corresponding vehicle may be determined as the tire wear lifespan of the corresponding vehicle.

Each tire may include two center grooves, a shoulder groove and a shoulder block groove.

In the instant case, an expected wear lifespan “A” of each tire groove at the driving distance “K” may be determined by the following equation.

A=K×(Initial Groove Depth−1.6)/(Initial Groove Depth−End Groove Depth)

The initial groove depth is the groove depth when the driving distance is zero, and the End groove depth is the groove depth when the driving distance is k. In the instant case, the expected wear lifespan of the tire of the vehicle may be determined as a minimum value of the expected wear lifespans of the all grooves of the tire.

As illustrated in reference numeral 320 of FIG. 3, variable factors for predicting tire wear lifespan in the learning modeling process may include vehicle information, driving condition information, tire information, and wheel alignment information. In the instant case, the variable factors may be input to a predetermined modeling function f(x) to which vehicle driving, tire tread, tire wear mechanism, or the like are applied, so that an expected wear lifespan for each tire groove may be determined.

FIG. 4 is a diagram for describing a learning algorithm according to various exemplary embodiments of the present invention.

Since the wear lifespan of a drive shaft (transfer of driving force) tire is usually low, the wear lifespan of tires of a corresponding vehicle may be determined by the wear lifespan of the drive shaft tire.

Therefore, when building an AI prediction model, it may be more effective to classify front-wheel drive vehicle and rear-wheel drive vehicle datasets for prediction, rather than using all practical test datasets.

For example, as shown in reference numeral 410, a learning algorithm according to various exemplary embodiments of the present invention may be implemented to predict the wear lifespan of a front wheel tire or all tires when a driving method is the front wheel drive type. On the other hand, when the driving method is the rear wheel drive type, as shown in reference numeral 420, the learning algorithm may be implemented to predict the wear lifespan of a rear wheel tire or all tires.

Predictive models for 2×2 combination of a driving method (front-wheel drive/rear-wheel drive) and a mounting position of a tire to be predicted (drive shaft/all tires) may be configured.

Furthermore, the tire wear database constructed based on the basic data may be divided as shown in FIG. 4 according to the driving method, and a separate predictive model may be produced.

FIG. 5 is a diagram for describing a data purification process for AI learning/prediction according to various exemplary embodiments of the present invention.

The tire wear prediction apparatus may convert all discrete (categorical) variables/qualitative variables, such as a power source type, a tire manufacturer, and a driving mode, into quantitative variables (S510). Reference numeral 610 of FIG. 6 shows an example of conversion of quantitative variables for a power source which is a feature variable.

The tire wear prediction apparatus may normalize the quantitative variables (S520). For example, a wheel alignment value having a small absolute numerical value may be normalized by substituting the wheel alignment value with a value between 0 and 100. Reference numeral 620 of FIG. 6 shows an example of normalization for a feature variable camber.

The tire wear prediction apparatus may supplement the predictive variables (S530). As an example, extreme values (outliers) among values of predictive variables may be eliminated. As an example, an outlier of target data may be eliminated based on 3 sigma. Here, 3 sigma may refer to a value in the range of 3 standard deviations from the average of a corresponding predictor value to both sides. Reference numeral 630 of FIG. 6 shows an example of eliminating an outlier of a tire groove wear lifespan which is a predictive variable.

The tire wear prediction apparatus may supplement the explanatory variables (S540). As an example, when a missing value exists among values of a previous dataset of an explanatory variable, the corresponding explanatory variables may be supplemented by replacing the corresponding missing value with an average value. As an example, for a tire tread physical property (Tg) value, the missing value may be replaced with an average value within corresponding classification after classification into all season and summer patterns. Reference numeral 640 of FIG. 6 shows an example of supplementing a missing value for an initial groove depth of a front wheel tire and tire tread physical properties, which are explanatory variables.

Data may be refined through the above-described S510 to S540 to construct a final training dataset (S550). Reference numeral 650 of FIG. 6 shows an example of an input variable (explanatory variable)/output variable (predictive variable) that has undergone the data purification process through S510 to S540.

FIG. 7 is a flowchart for describing an operation mechanism of a tire wear prediction apparatus according to various exemplary embodiments of the present invention.

Referring to FIG. 7, the tire wear prediction apparatus may import a tire wear database, produced based on basic data, from an internal memory (or an external device/server), and then perform preprocessing the data stored in the tire wear database to generate a dataset (S710 to S720). Here, the preprocessing may include conversion from discrete/qualitative variables to quantitative variables, normalization of quantitative variables, removal of extreme numerical values among predictive variables, supplementation of explanatory variables with missing values, and/or the like.

The tire wear prediction apparatus may classify a dataset for each vehicle driving method (S730). Here, the vehicle driving method may include a front wheel drive method, a rear wheel drive method, and a 4WD method.

The tire wear prediction apparatus may optimize a hyper parameter to be applied to a learning algorithm (S740).

The tire wear prediction apparatus may perform machine learning based on the optimized hyper parameter to predict tire wear performance (S750). In the instant case, a prediction result of the tire wear performance may be transmitted to an in-vehicle display device, a vehicle controller, a driver terminal or a vehicle manufacturer server, a mobility operator server, and the like to be utilized for various purposes.

For example, the tire wear prediction result may be processed to generate information related to an expected drivable mileage and an expected change progress for mileage, which are then provided to a driver through an in-vehicle display device—for example, a cluster, a HUD (Head Up Display), and the driver's smart device.

As various exemplary embodiments of the present invention, the tire wear prediction result may be utilized for vehicle active control based on a tire wear status. For example, the tire wear prediction result may be utilized for real-time optimization of parameters related to vehicle driving, such as braking/turning/suspension/steering/driving.

As yet another example, the tire wear prediction result may be provided to a mobility vehicle driving operator and used for a preemptive maneuver for tire maintenance. For example, the tire wear prediction result may be processed to generate vehicle management related information, such as information on a tire position change and replacement time, and driving usage condition analysis for further usage.

The tire wear prediction apparatus according to various exemplary embodiments of the present invention may obtain information from various sensors provided in the vehicle and perform machine learning for tire wear prediction.

For example, the tire wear prediction apparatus may obtain information such as rapid acceleration, sudden braking, and turning required for driving mode analysis from an acceleration sensor built in an airbag control unit.

Furthermore, the tire wear prediction apparatus may obtain vehicle wheel alignment information detected by an electronic suspension device, obtain vehicle weight change information and vehicle attitude change information detected by an auto leveling device, and obtain tire pressure change information from a tire pressure monitoring system (TPMS).

Furthermore, the tire wear prediction apparatus may obtain information related to driving climate environment from an outdoor temperature sensor built in an air conditioner.

In the case of learning using an artificial intelligence algorithm, the usage of resources of a controller (CPU/PROCESSOR)—that is, processing load—is high, but in the case of an artificial intelligence algorithm that has been trained, the usage of resources of the controller may be significantly reduced when processing/analyzing/judging sensor information.

Accordingly, the tire wear prediction apparatus (or tire wear prediction processor) according to the exemplary embodiment may be mounted and driven on at least one of controllers mounted on the vehicle. As an example, the tire wear prediction apparatus may be mounted and driven on a specific vehicle ECU or ACU.

FIG. 8 is a graph showing tire wear lifespans according to practical vehicle driving evaluation and prediction results of tire wear lifespan using a tire wear learning algorithm according to various exemplary embodiments of the present invention.

Referring to FIG. 8, the tire wear lifespan according to the practical vehicle driving evaluation based on the minimum tire wear lifespan and the tire wear lifespan prediction results through AI learning show that the error rate is about 5.9%.

FIG. 9 shows the AI learning prediction result for the rear wheel wear lifespan ratio according to a change in rear wheel camber.

Referring to FIG. 9, when the AI learning method according to various exemplary embodiments of the present invention is applied, it is shown that the tire wear tendency according to a change in rear wheel camber is consistent.

The operations of the method or the algorithm described in connection with the exemplary embodiments included herein may be embodied directly in hardware or a software module executed by the processor, or in a combination thereof. The software module may reside on a storage medium (that is, the memory and/or the storage) such as a RAM, a flash memory, a ROM, an EPROM, an EEPROM, a register, a hard disk, a removable disk, and a CD-ROM.

The exemplary storage medium may be coupled to the processor, and the processor may read information out of the storage medium and may record information in the storage medium. Alternatively, the storage medium may be integrated with the processor. The processor and the storage medium may reside in an application specific integrated circuit (ASIC). The ASIC may reside within a user terminal. In another case, the processor and the storage medium may reside in the user terminal as separate components.

The above description is merely illustrative of the technical idea of the present invention, and various modifications and variations may be made without departing from the essential characteristics of the present invention by those skilled in the art to which various exemplary embodiments of the present invention pertains. Accordingly, the exemplary embodiment included in various exemplary embodiments of the present invention is not intended to limit the technical idea of the present invention but to describe the present invention, and the scope of the technical idea of the present invention is not limited by the embodiment. The scope of protection of the present invention may be interpreted by the following claims, and all technical ideas within the scope equivalent thereto may be construed as being included in the scope of the present invention.

The present invention has the advantage of providing a tire wear prediction method using artificial intelligence machine learning and an apparatus therefor.

Furthermore, the present invention has the advantage of providing a tire wear prediction method using AI machine learning configured for preemptively taking action for future problems by facilitating the development of a virtual vehicle through early prediction and analysis of tire wear performance when evaluating tire wear before practical driving, and an apparatus therefor.

Furthermore, the present invention has the advantage of providing a multi output regression prediction model using a machine learning technique, configured for quantitatively performing data-based tire wear prediction based on a learning/prediction database frame built for development of a machine learning algorithm.

Furthermore, the present invention has the advantage of providing a tire wear prediction method using AI machine learning configured for facilitating real-time active control and operation management of autonomous vehicles/mobility vehicles by linking multi output regression prediction models using artificial intelligence machine learning techniques to vehicle controllers, infotainment systems, and mobility operators, and an apparatus therefor.

Furthermore, the present invention has the advantage of providing a tire wear prediction method using AI machine learning configured for relative comparison and contribution analysis of wear features for each tire wear influence factor, and an apparatus therefor.

Furthermore, the present invention has the advantage of reducing costs by replacing practical vehicle tire wear evaluation through wear prediction based on artificial intelligence machine learning.

Furthermore, various effects may be provided that are directly or indirectly understood through the present invention.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present invention have been presented for purposes of illustration and description. They are not intended to be exhaustive or to limit the present invention to the precise forms disclosed, and obviously many modifications and variations are possible in light of the above teachings. The exemplary embodiments were chosen and described to explain certain principles of the present invention and their practical application, to enable others skilled in the art to make and utilize various exemplary embodiments of the present invention, as well as various alternatives and modifications thereof. It is intended that the scope of the present invention be defined by the Claims appended hereto and their equivalents.

What is claimed is:

1. A method for predicting tire wear in an apparatus mounted in a vehicle, the method comprising:
importing, by a processor, a tire wear database generated according to basic data;
creating, by the processor, a dataset by preprocessing the basic data;
classifying, by the processor, the dataset for each vehicle driving method;
optimizing, by the processor, a hyper parameter for machine learning based on the classified dataset; and
predicting, by the processor, a tire wear lifespan of the vehicle by performing the machine learning on the optimized hyper parameter.

2. The method of claim 1,
wherein the basic data includes explanatory variables and predictive variables obtained through a tire wear test of an actual vehicle, and
wherein the explanatory variables include at least one of vehicle information, vehicle driving information, tire information, and wheel alignment information, and the predictive variables include a wear lifespan of each tire groove.

3. The method of claim 2, wherein the preprocessing includes at least one of:
converting discrete variables and qualitative variables into quantitative variables;
normalizing the quantitative variables;
eliminating extreme values from the predictive variables; and
compensating for missing values of the explanatory variables.

4. The method of claim 1, wherein the hyper parameter is optimized by eliminating a factor with importance lower than a predetermined value from the classified dataset through importance analysis for each tire wear factor based on Least Absolute Shrinkage and Selection Operator (LASSO) model.

5. The method of claim 1, wherein the tire wear lifespan is predicted based on a multi output regression analysis technique, and is predicted through the multi output regression analysis technique.

6. The method of claim 5,
wherein the multi output regression analysis technique includes a random forest technique and a stochastic gradient boosting technique, and
wherein one of the random forest technique and the stochastic gradient boosting technique is selectively used based on a number of the classified datasets.

7. The method of claim 1, further including:
outputting, by the processor, predicted tire lifespan information through an output device provided in the vehicle; and
transmitting, by the processor, the predicted tire lifespan information to the other device.

8. The method of claim 7, wherein the other device includes at least one of a vehicle controller, a vehicle developer server, a driver terminal, and a mobility operator server.

9. The method of claim 8, further including:
optimizing, by the processor, a vehicle driving-related parameter by performing vehicle active control based on the predicted tire lifespan information,
wherein the vehicle active control includes at least one of braking control, suspension control, steering wheel control, and turning control.

10. The method of claim 1, wherein the basic data is collected from a sensor provided in the vehicle, and the basic data includes at least one of driving mode analysis information detected by an acceleration sensor built in an airbag control unit, wheel alignment change information detected by an electronic suspension device, vehicle weight change information detected by an auto-leveling device, tire pressure change information detected by a tire pressure monitoring system (TPMS), and driving climate environment information detected by an outdoor air temperature sensor in an air conditioner.

11. An apparatus of predicting tier wear, the apparatus comprising:
a memory; and
a processor electrically connected to the memory,
wherein the processor is configured to import a tire wear database generated based on basic data from the memory or an external device, to generate a dataset by preprocessing the basic data, to classify the dataset for each vehicle driving method, to optimize a hyper parameter for machine learning based on the classified dataset, and to predict a tire wear lifespan of the vehicle by performing machine learning on the optimized hyper parameter.

12. The apparatus of claim 11,
wherein the basic data includes explanatory variables and predictive variables obtained through a tire wear test of an actual vehicle, and
wherein the explanatory variables include at least one of vehicle information, vehicle driving information, tire information, and wheel alignment information, and the predictive variables include a wear lifespan of each tire groove.

13. The apparatus of claim 12, wherein the processor includes at least one of:
means for converting discrete variables and qualitative variables into quantitative variables;
means for normalizing the quantitative variables;
means for eliminating extreme values of the predictive variables; and
means for compensate for missing values of the explanatory variables.

14. The apparatus of claim 11, wherein the hyper parameter is optimized by eliminating a factor with importance lower than a predetermined value from the classified dataset through importance analysis for each tire wear factor based on Least Absolute Shrinkage and Selection Operator (LASSO) model.

15. The apparatus of claim 11, wherein the tire wear lifespan is predicted based on a multi output regression analysis technique, and is predicted through the multi output regression analysis technique.

16. The apparatus of claim 15,
wherein the multi output regression analysis technique includes a random forest technique and a stochastic gradient boosting technique, and
wherein the processor is configured to selectively select one of the random forest technique and the stochastic gradient boosting technique based on a number of the classified datasets.

17. The apparatus of claim 11, wherein the processor includes at least one of means for controlling output of the predicted tire lifespan information or information processed based on the predicted tire lifespan information through an output device provided in the vehicle, and means for controlling transmission of the predicted tire lifespan information to the other device.

18. The apparatus of claim 17, wherein the other device includes at least one of a vehicle controller, a vehicle developer server, a driver terminal, and a mobility operator server.

19. The apparatus of claim 18,
wherein the processor is configured to optimize a vehicle driving-related parameter by performing vehicle active control based on the predicted tire lifespan information, and
wherein the vehicle active control includes at least one of braking control, suspension control, steering wheel control, and turning control.

20. The apparatus of claim 11,
wherein the basic data is collected from a sensor provided in the vehicle, and
wherein the basic data includes at least one of driving mode analysis information detected by an acceleration sensor built in an airbag control unit, wheel alignment change information detected by an electronic suspension device, vehicle weight change information detected by an auto-leveling device, tire pressure change information detected by a tire pressure monitoring system (TPMS), and driving climate environment information detected by an outdoor air temperature sensor in an air conditioner.
